(19) United States
(12) Patent Application Publication
(10) Pub. No.: US 2014/0038108 A1
(43) Pub. Date: Feb. 6, 2014

(54) Light Emitting Diode Apparatus for Curing an Emulsion

(71) Applicant: Louis D'Amelio, Sterling Forest, NY (US)

(72) Inventor: Louis D'Amelio, Sterling Forest, NY (US)

(21) Appl. No.: 13/955,426

(22) Filed: Jul. 31, 2013

Related U.S. Application Data
(60) Provisional application No. 61/678,168, filed on Aug. 1, 2012.

(51) Int. Cl. B05D 3/06; G03F 7/12

(52) U.S. Cl. CPC B05D 3/067; G03F 7/12
USPC 430/308; 250/492.1

(57) ABSTRACT

An apparatus and method for curing a photo activated emulsion. The apparatus is a light emitting apparatus is a plurality of light emitting diodes (LED's) attached to a circuit board. The LED's are used to quickly and efficiently cure a photo sensitive emulsion on a mesh screen for use in silk screening.

### CROSS-REFERENCE

This application claims priority from Provisional Patent Application Ser. No. 61/687,168 filed Aug. 1, 2012.

### FIELD OF THE INVENTION

This invention pertains generally to a light emitting diode apparatus for curing a photo sensitive emulsion, and more particularly to an apparatus for curing a photo sensitive emulsion on a master silk screen for use in transferring ink images onto fabric and a method of using the same.

### BACKGROUND

Silk-screening is a process, common in the textile industry, where a design or image is created on a fabric by forcing ink through a screen having a negative of the design into the fabric. A master screen with a negative image is created by coating a mesh screen with a photo sensitive emulsion. The desired image is created on a separate surface with a photographic masking agent and then placed over the coated master screen. Then the screen is exposed to an electromagnetic radiation source thereby activating and solidifying the emulsion on the screen where it is not blocked by the masking agent. After the appropriate exposure time, any non-activated emulsion is rinsed off of the screen with a solvent such as water leaving the negative image on the master screen. The screen is then placed over a fabric or piece of cloth such as a tee shirt, and ink is pressed or rolled through the openings in the screen not blocked by the activated emulsion. The ink transfers onto the fabric allowing the image to be inked into the fabric.

The photo sensitive emulsions are applied to the screen and then typically activated or dried with a light source such as a fluorescent or metal halide light bulb which emit light at a wide range of wavelengths. Traditional light sources used for curing emulsions in the textile and printing industries have multiple drawbacks such as limited bulb life, high energy consumption, faster bulb output level degradation, high heat output, and long exposure times. Generally, the faster the emulsion is cured, the more efficient the silk-screening process becomes.

Consequently, there exists a need for a device to provide a universal replacement light source for many types of visible and ultraviolet light sources used for curing emulsions. The present invention discloses a light emitting apparatus for curing an emulsion activated by a visible or ultraviolet light. The light emitting apparatus may comprise a single strip or multiple strips of lights connected together to provide light to a greater surface area. The light emitting apparatus may emit light in a visible or ultraviolet range of wavelengths depending on the requirements of the emulsion to be cured. Additionally, the emitted light may be emitted in a narrow band so as to optimize the output of light and decreasing the curing time for the emulsion.

### SUMMARY

The following presents a simplified summary in order to provide a basic understanding of some aspects of the disclosed invention. This summary is not an extensive overview, and it is not intended to identify key/critical elements or to delineate the scope thereof. Its sole purpose is to present some concepts in a simplified form as a prelude to the more detailed description that is presented later.

The subject matter disclosed and claimed herein, in one aspect thereof, comprises a light emitting apparatus for curing a photo sensitive emulsion. The light emitting apparatus comprises at least one circuit board and a plurality of light emitting diodes (LEDs) mounted on or integrated within the at least one circuit board. The plurality of LEDs are aligned in a row on the at least one circuit board. Additionally, the at least one circuit board may be attached to a plurality of circuit boards to create an array of the plurality of LEDs. The light emitting apparatus may be used as a universal replacement for traditional visible and ultraviolet light sources in the textile industry.

Each of the plurality of light emitting diodes emit a light at a wavelength of approximately between 350 and 420 nanometers, This narrow range of wavelengths reacts quickly with most of the photo sensitive emulsions used in silk screening. This significantly reduces the amount of time that the photo sensitive emulsion must be exposed to the light.

Furthermore, in a preferred embodiment, a method is provided for curing a photo sensitive emulsion onto a mesh screen for use in a silk screening process. The method comprises the steps of: coating the mesh screen with the photo sensitive emulsion; covering a part of the mesh screen with an image comprising a photographic masking agent; exposing the mesh screen with the image to a light emitting diode light source to selectively activate the photo sensitive emulsion not blocked by the photographic masking agent; and rinsing off any non-activated photo sensitive emulsion.

To the accomplishment of the foregoing and related ends, certain illustrative aspects are described herein in connection with the following description and the annexed drawings. These aspects are indicative of the various ways in which the principles disclosed herein can be practiced and all aspects and equivalents thereof are intended to be within the scope of the claimed subject matter. Other advantages and novel features will become apparent from the following detailed description when considered in conjunction with the drawings.

### BRIEF DESCRIPTION OF THE DRAWINGS

FIG. 1 illustrates a perspective view of a light emitting apparatus in accordance with the disclosed architecture.

FIG. 2 illustrates a side view of the light emitting apparatus in accordance with the disclosed architecture.

FIG. 3 illustrates a perspective view of a plurality of the light emitting apparatuses in accordance with the disclosed architecture.

FIG. 4 illustrates a perspective view of the plurality of the light emitting apparatuses in accordance with the disclosed architecture.

### DETAILED DESCRIPTION

Reference is now made to the drawings, wherein like reference numerals are used to refer to like elements throughout. In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives falling within the spirit and scope of the claimed subject matter. The invention relates generally to a

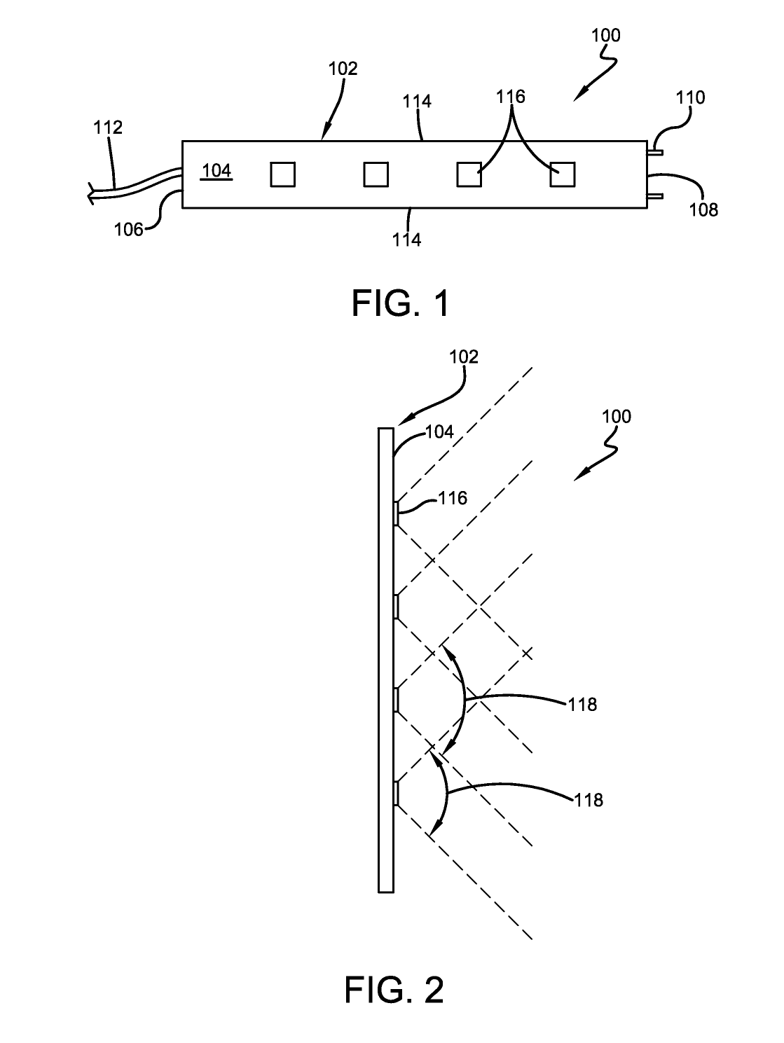

Referring initially to the drawings, FIG. 1 illustrates a light emitting apparatus 100. The light emitting apparatus 100 is typically used in curing a photo sensitive emulsion onto a mesh screen, such as those used in a silk screening process. The light emitting apparatus 100 may be used as a light source for applications requiring a visible or an ultraviolet light source. The light emitting apparatus 100 comprises a circuit board 102 and a plurality of LEDs 116.

The circuit board 102 is typically one or more aluminum heat dissipating circuit boards that are connectable. The circuit board 102 comprises a top 104, a pair of sides 114, a first end 106, and a second end 108. The plurality of LEDs 116 are generally attached to or integrated into the top 104 of the circuit board 102. The first end 106 and the second end 108 may comprise a connecting element 110. The connecting element 110 permits a user to connect several of the circuit boards 102 together in series. The first end 106 of one circuit board simply plugs into the second end 108 of a second circuit board so that they are in electrical communication. The connecting element 110 may connect to a power cord 112 for plugging into an outlet or battery power source.

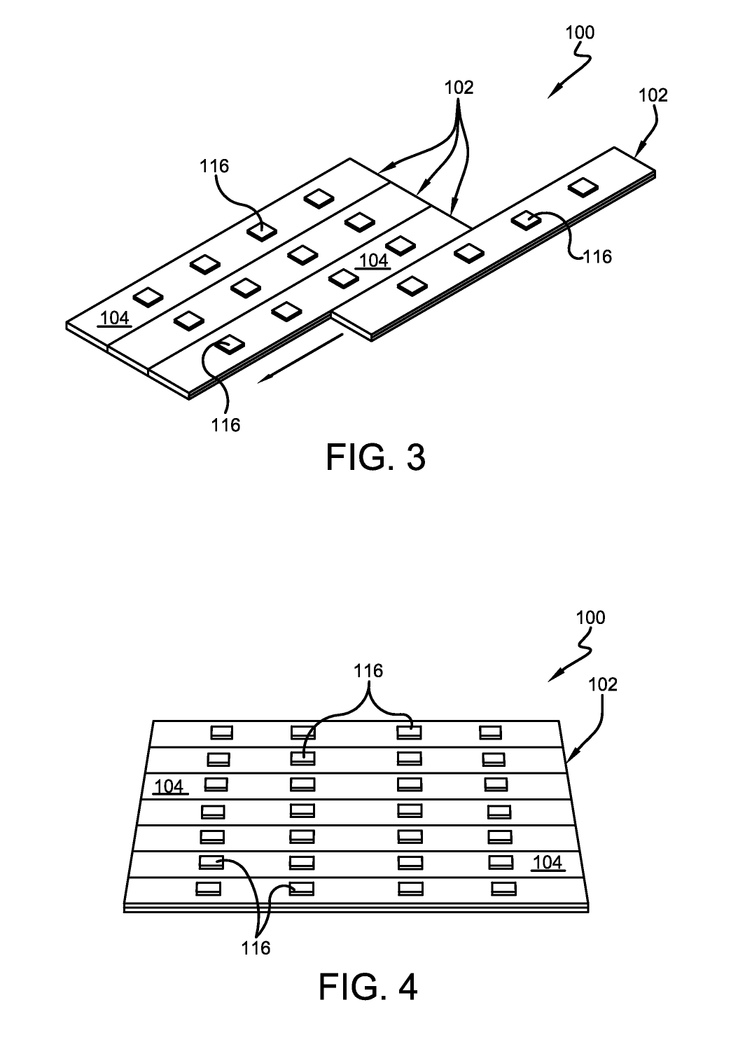

As illustrated in FIGS. 3 and 4, the circuit board 102 may be connected to additional circuit boards in a side to side, or parallel array. Each of the pair of sides 114 of the circuit board 102 may slidably connect to another circuit board. This arrangement allows for a larger simultaneous exposure of light. This is advantageous as an optimal number of LED bulbs may be selected that directly correlates to the size of the mesh screen and the exposure area thereby reducing energy usage.

As illustrated in FIGS. 1 and 2, the plurality of LEDs 116 are located in the top 104 of the circuit board 102 so that each of the plurality of LEDs 116 emits light at a light beam angle 118 of between approximately 30 and 160 degrees. This allows for a more directed beam of light which is more efficient than emitting light at 360 degrees. For example, traditional bulbs used in this process, such as metal halide bulbs, emit light at 360 degrees. Most of this emitted light is wasted energy as it is not directed onto the surface having the emulsion. With all of the light from the light emitting apparatus 100 being directed at the mesh screen, the photo sensitive emulsion is cured more efficiently. The plurality of LED's 116 may also have a narrower light beam angle 118, such as approximately 90 to 145 degrees for example, to create an even more intense beam of light as well.

The silk screening process requires a template for transferring an image onto a fabric. The template is the mesh screen with the cured photo sensitive emulsion. The photo sensitive emulsion may comprise a photo emulsion, a polymer emulsion, a Diazo-photo polymer emulsion, a capillary emulsion film, and the like, or any other photo sensitive emulsion or film known to one of skill in the art. The photo sensitive emulsions used in silk screening generally react best to a narrow wavelength of light. Preferred wavelengths for these emulsions are generally in the lower visible spectrum (420 to 400 nm) or the upper ultra violet spectra (350 to 400 nm). To create the template, a negative of the desired image is created using a photographic masking agent. The negative is placed over the mesh screen coated with the photo sensitive emulsion and exposed to the light.

Each of the plurality of LEDs 116 typically have an emission spectra and emit light at a wavelength of approximately between 350 and 420 nanometers. As discussed supra, the ideal wavelength is dependant on the specific photo sensitive emulsion used. The plurality of LEDs 116 are LEDs that only emit light specifically at these wavelengths further reducing energy consumption. For example, a preferred embodiment of the invention employs the plurality of LEDs 116 emitting light at a wavelength of approximately between 402 and 410 nanometers. Furthermore, the plurality of LEDs 116 are typically multi-chip bulb LEDs. This is advantageous as it is the equivalent of using three or more high power LEDs. The multi-chip LED bulb has a more powerful energy output than traditional LED bulbs.

Next, a method is described for curing a photo sensitive emulsion onto a mesh screen for use in a silk screening process. The method comprises coating the mesh screen with the photo sensitive emulsion. A negative of an image to be transferable to a fabric is created using a photographic masking agent which is placed on the mesh screen. The mesh screen is then placed adjacent to the light emitting apparatus 100 so that the plurality of LEDs 116 are within four inches of the mesh screen, and the plurality of LEDs 116 are activated. Ideally, the distance of separation between the plurality of LEDs 116 and the mesh screen is approximately between two and four inches. This distance is ideal because as it allows for the most even emission of light energy resulting in an even exposure on the mesh screen. However, the plurality of LEDs 116 may be moved further away from the mesh screen as well. For example, placing the plurality of LEDs 116 approximately 12 inches away would allow several mesh screens to be exposed to the plurality of LEDs 116 simultaneously. While this would slightly increase the exposure time, the exposure area would increase exponentially thereby increasing efficiency.

The plurality of LEDs 116 are activated generally less than three minutes. Traditional light sources require significantly longer times to activate the emulsion. As the speed of curing is directly dependant on the specific activating wavelength of the emulsion, the process may be sped up so that exposure to the plurality of LEDs 116 is less than 30 seconds. For example, using an emulsion of a typical photo polymer, and the plurality of LEDs 116 emitting a wavelength of approximately between 402 and 410 nanometers, the time of exposure may be reduced to between approximately three to 15 seconds. The specific exposure time will be dependant on the specific emulsion and the wavelengths of emitted light.

Once cured, any inactivated emulsion that was blocked by the photographic mashing agent may be rinsed off with water or a similar solvent leaving the negative image unblocked in the mesh screen. The length of exposure is also directly proportional to the thickness of the photo sensitive emulsion. Therefore, decreasing the distance form the plurality of LEDs 116 m decrease curing time. An additional step may comprise using a vacuum during the exposure to decrease curing time as well.

Other variations are within the spirit of the present invention. Thus, while the invention is susceptible to various modifications and alternative constructions, a certain illustrated embodiment thereof is shown in the drawings and has been described above in detail. It should be understood, however, that there is no intention to limit the invention to the specific form or forms disclosed, but on the contrary, the intention is to cover all modifications, alternative constructions, and equivalents falling within the spirit and scope of the invention, as defined in the appended claims.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not pose a limitation on the scope of the invention unless otherwise claimed. No language in the specification should be construed as indicating any non-claimed element as essential to the practice of the invention.

Preferred embodiments of this invention are described herein. Variations of those preferred embodiments may become apparent to those of ordinary skill in the art upon reading the foregoing description. The inventor expects skilled artisans to employ such variations as appropriate, and the inventor intends for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A light emitting apparatus for use in curing a photo sensitive emulsion onto a mesh screen comprising:
at least one circuit board; and
a plurality of light emitting diodes mounted on a top surface of the at least one circuit board, wherein each of the plurality of light emitting diodes emit a light at a wavelength ranging from approximately between 350 and 420 nanometers and at a light beam angle of approximately between 90 and 160 degrees.

2. The light emitting apparatus of claim 1, wherein the plurality of light emitting diodes are placed within twelve inches of the photo sensitive emulsion when activated.

3. The light emitting apparatus of claim 2, wherein the plurality of light emitting diodes are activated for between approximately three and fifteen seconds to cure the photo sensitive emulsion.

4. The light emitting apparatus of claim 2, wherein the wavelength of the emitted light is approximately between 402 and 410 nanometers.

5. The light emitting apparatus of claim 1, wherein the photo sensitive emulsion comprises a photo emulsion, a polymer emulsion, a Diazo-photo polymer emulsion, or a capillary emulsion film.

6. The light emitting apparatus of claim 1, wherein each of the plurality of light emitting diodes are a multi-chip bulb.

7. A light emitting apparatus for use in curing a photo sensitive emulsion onto a mesh screen comprising:
at least one circuit board; and
a plurality of light emitting diodes mounted on a top surface of the at least one circuit board, wherein the plurality of light emitting diodes emit a light at a wavelength ranging from approximately between 350 and 420 nanometers and wherein the photo sensitive emulsion cures within three minutes of activation of the light emitting diodes.

8. The light emitting apparatus of claim 7, wherein the plurality of light emitting diodes are placed within four inches of the photo sensitive emulsion when activated.

9. The light emitting apparatus of claim 7, wherein the plurality of light emitting diodes are placed approximately between two and four inches from of the photo sensitive emulsion when activated.

10. The light emitting apparatus of claim 9, wherein the emitted light is emitted at a light beam angle of approximately between 90 and 145 degrees.

11. The light emitting apparatus of claim 9, wherein the photo sensitive emulsion cures within fifteen seconds of activation of the light emitting diodes.

12. The light emitting apparatus of claim 11, wherein the wavelength of the emitted light is approximately between 402 and 410 nanometers.

13. A method of curing a photo sensitive emulsion onto a mesh screen for use in a silk screening process, the method comprising;
coating the mesh screen with the photo sensitive emulsion;
placing an image comprising a photographic masking agent on the coated mesh screen;
exposing the coated mesh screen and the image to a light emitting diode light source emitting a light with a wavelength of approximately between 350 and 420 nanometers to activate the photo sensitive emulsion not blocked by the photographic masking agent, wherein the light emitting diodes are within four inches of the coated mesh screen and the image;
removing the inactivated emulsion with a solvent.

14. The method of claim 13, wherein the coated mesh screen is exposed to the light emitting diode source for less than 30 seconds.

15. The method of claim 14, wherein the wavelength of the emitted light is between approximately 400 and 420 nanometers.

16. The method of claim 13, wherein the wavelength of the emitted light is between approximately 402 and 410 nanometers and the coated mesh screen is exposed to the light emitting diode source for approximately between five and ten seconds.

17. The method of claim 14 wherein each of the plurality of light emitting diodes are a multi-chip bulb.

18. The method of claim 17, wherein the emitted light is emitted at a light beam angle of approximately between 90 and 140 degrees.

19. The method of claim 18, wherein the length of exposure of the coated mesh screen to the light emitting diode source is directly proportional to a thickness of the photo sensitive emulsion and the distance of the photo sensitive emulsion from the light emitting diode source.

20. The method of claim 19, further comprising the step of exposing the coated mesh screen and the image to a light emitting diode light source in a vacuum.
